(19) United States
(12) Patent Application Publication
(10) Pub. No.: US 2026/0205149 A1
(43) Pub. Date: Jul. 16, 2026

(54) REDUCING COMMON MODE NOISE IN A TRANSMITTER

(71) Applicant: NVIDIA Corporation, Santa Clara, CA (US)

(72) Inventors: Anish Morakhia, Mountain View, CA (US); Dai Dai, Sunnyvale, CA (US); William Weng, Zhubei City (TW)

(21) Appl. No.: 19/022,110

(22) Filed: Jan. 15, 2025

(51) Int. Cl. H04B 1/04; H03K 3/017; H03K 5/1252

(52) U.S. Cl. CPC H04B 1/04; H03K 3/017; H03K 5/1252

(57) ABSTRACT

Technologies for correcting transmitter common mode (CM) voltage deviations in serial data are described. A transmitter device includes a clock source to supply a plurality of phase signals, and a resonant structure to receive the plurality of phase signals and generate a plurality of sinusoidal phase signals. The transmitter device also includes a first serializer to receive parallel data and convert the parallel data to serial data using the plurality of sinusoidal phase signals, and a transmitter coupled to an output of the first serializer. The transmitter device also includes a duty-cycle correction circuit coupled ton an output node of the transmitter. The duty-cycle correction circuit can detect a CM voltage deviation in the serial data, and correct the CM voltage deviation by applying a voltage offset to the plurality of sinusoidal phase signals.

### TECHNICAL FIELD

At least one embodiment pertains to processing resources used to reduce common mode noise in a transmitter. For example, at least one embodiment pertains to a transmitter device with a duty-cycle correction circuit that detects a common mode voltage deviation in serial data and corrects the CM voltage deviation by applying a voltage offset to sinusoidal clock signals used to serialize the serial data.

### BACKGROUND

Transmitter devices are electronic circuits that generate and send signals to other devices for communication or control purposes. One aspect of transmitter operation is maintaining signal integrity, which refers to the quality and reliability of the transmitted signal. Some transmitter devices use a serializer. A serializer is a circuit or system that converts parallel data into a serial data stream, allowing multiple bits of data to be transmitted sequentially over a single data line or channel. A serializer can enable high-bandwidth data to be transmitted efficiently across bandwidth-limited channels. The serializer accepts multiple parallel data lines as input, where each line typically represents a bit from a multi-bit word, such as an 8-bit input representing one byte of data. It then shifts these parallel bits out sequentially, one bit at a time, onto a single output line. This process is synchronized to a clock signal, and the serializer's output clock operates at a much higher frequency than the parallel input clock to transmit all the bits within one cycle of the parallel input clock. Transmitters can be sensitive to a common mode voltage of the clock and results in a large transmitter (TX) common mode noise when the clock has a duty cycle of 50%, especially for skewed process corners (i.e., slow-fast (SF)/Fast-Slow (FS)). Duty cycle refers to the proportion of time that a signal is active (i.e., the “on” time) versus the total time it takes to complete one cycle. The TX common mode noise can degrade link performance especially for short channels.

### BRIEF DESCRIPTION OF DRAWINGS

Various embodiments in accordance with the present disclosure will be described with reference to the drawings, in which:

FIG. 1A illustrates an example communication system with a duty-cycle correction circuit according to at least one embodiment.

FIG. 1B illustrates a block diagram of an example communication system employing a transmitter with a duty-cycle correction circuit according to at least one embodiment.

FIG. 2 is a block diagram of a transmitter device with a duty-cycle correction circuit according to at least one embodiment.

FIG. 3 illustrate timing diagrams of various signal waveforms before and after correction of the CM voltage deviation according to at least one embodiment.

FIG. 4 is a graph showing example bit error rate (BER) for multiple calibration codes according to at least one embodiment.

FIG. 5 is a schematic diagram of an analog duty-cycle correction loop and a voltage reference digital-to-analog converter (Vref DAC) according to at least one embodiment.

FIG. 6 is a block diagram of an interface circuit with duty-cycle detection and correction logic and an analog duty-cycle correction loop according to at least one embodiment.

FIG. 7 is a flow diagram of an example method 700 for correcting a common mode voltage deviation according to at least one embodiment.

FIG. 8 illustrates an example computer system including a spectrum hardware engine and an error correction block according to at least one embodiment.

FIG. 9 is a block diagram of a computing system having two processing devices coupled to each other and multiple networks according to at least one embodiment.

FIG. 10 is a block diagram of a computing system having a central processing unit (CPU) and a graphics processing unit (GPU) in a single integrated circuit according to at least one embodiment.

FIG. 11 is a block diagram of a computing system having tensor core graphics processing units (GPUs) according to at least one embodiment.

### DETAILED DESCRIPTION

Technologies for correcting transmitter common mode (CM) voltage deviations in serial data are described. The following description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid obscuring the present disclosure unnecessarily. Thus, the specific details set forth are merely exemplary. Particular implementations may vary from these exemplary details and still be contemplated to be within the scope of the present disclosure.

As described above, transmitters can be sensitive to a CM voltage of a clock, and the TX common mode noise can degrade link performance especially for short channels. For example, for SerDes applications targeting speeds at 200 Gpbs or greater, a quarter rate topology employing a clock greater than 25 GHz and a 4:1 data serializer can be used to transmit PAM4 (Pulse Amplitude Modulation 4-level) signals. To lower power consumption, resonant structures can be used in the clock path. The resonant structures produce a sine-wave like clock for a local clock buffer or pulse generator to use. Not having a rail-to-rail clock makes a transmitter driver sensitive to the CM voltage of the clock and results in large TX common mode noise, especially for skewed processor corner (SF/FS) when clock duty cycle is set to 50%.

Aspects and embodiments of the present disclosure address these problems and others by providing a transmitter device that is designed to reduce common mode noise, particularly in high-speed SerDes applications. The transmitter device can use a digitally-assisted TX data pattern-based scheme to sense deviations of the TX common mode voltage from a target voltage and change an average voltage to minimize the TX common mode noise. Aspects and embodiments of the present disclosure can be used in any N-rate TX clocking system, where is equal to or greater than 2 (i.e., N≥2). In some embodiments, the transmitter uses a quarter rate topology with a clock greater than 25 GHz and a 4:1 data serializer to transmit PAM4 signals, while reducing power consumption and common mode noise. The resonant structures in the clock path can create sine-wave-like clocks from a rectangular-like clock, but reduce power consumption. The sine-wave-like clocks can be different sinusoidal phase signals with different relative phases to one another. A pulse generator in the 4:1 data serializer is sensitive to the CM voltage of the clock. Because the data serializer's sensitivity to CM voltage, which leads to noise, a duty-cycle correction circuit can be used to detect and correct CM voltage deviations by applying a voltage offset to the sinusoidal phase signals. In some embodiments, the duty-cycle correction circuit can include a calibration analog-to-digital converter (ADC) and state machine logic (e.g., a finite state machine (FSM) to detect CM voltage deviations and determine one or more control codes for adjustment. A low-pass filter (LPF) can be used to filter the output signal before it is processed by the calibration ADC. An analog duty-cycle correction loop can be used to adjust the average voltage of the sinusoidal phase signals. The device can generate and/or use a direct current (DC) balanced clock pattern to help detect and correct for the CM voltage deviations. The DC balanced clock patterns can be used in a digitally-assisted TX data pattern-based scheme to sense the CM voltage deviations of a TX common mode voltage from a target voltage and change the DC voltage (i.e., average voltage) to minimize the CM noise.

Aspects and embodiments of the present disclosure can be used in any communication link that uses an N-rate TX clocking system, where is equal to or greater than 2 (i.e., N≥2). The communication link can be a Serializer-Deserializer (SerDes) link, an NVLink, cellular networking, PCIe, Ethernet, InfiniBand, Ground Reference Signal (GRS), Chip-to-Chip (C2C), Die-to-Die (D2D), LPI (low power interface) or LLI (low latency interface), or the like. Aspects and embodiments of the present disclosure can be used in various applications, including communication applications.

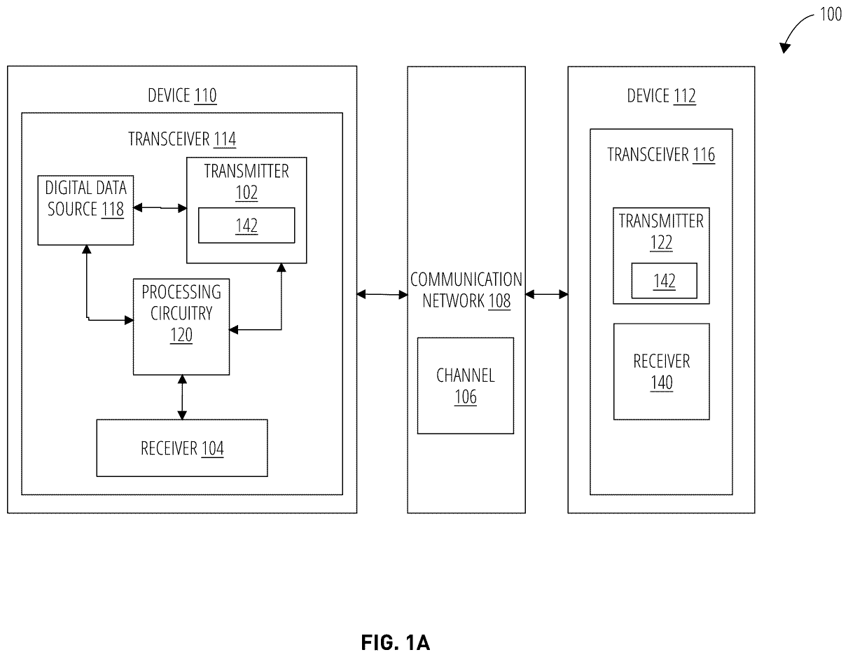

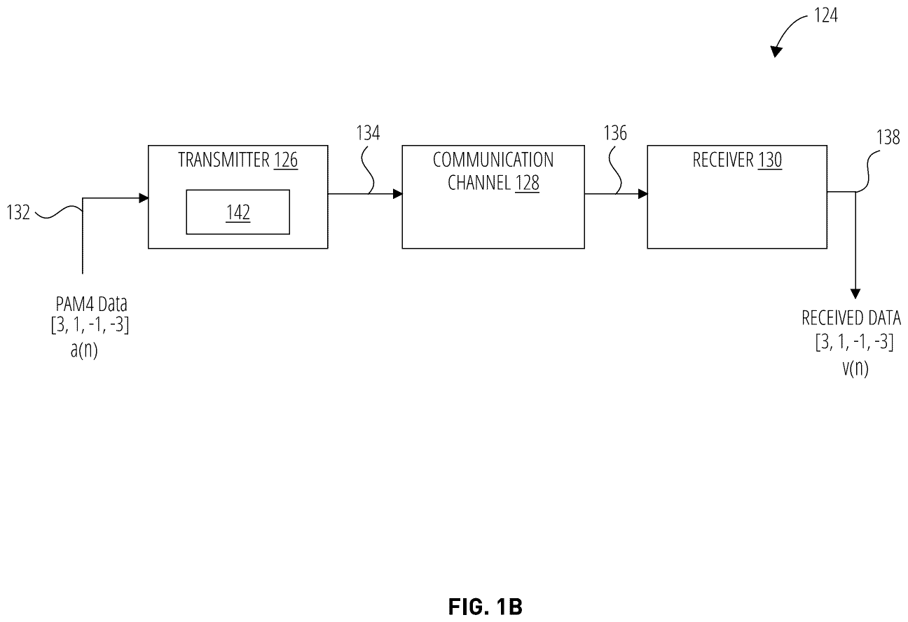

FIG. 1A illustrates an example communication system 100 with a duty-cycle correction circuit 142 according to at least one embodiment. The communication system 100 includes a device 110, a communication network 108 including a communication channel 106, and a device 112. In at least one embodiment, the devices 110 and 112 are integrated circuits of a Personal Computer (PC), a laptop, a tablet, a smartphone, a server, a collection of servers, or the like. In some embodiments, the devices 110 and 112 may correspond to any appropriate type of device that communicates with other devices also connected to a common type of communication network 108. According to embodiments, the transmitter 102 and 122 of devices 110 or 112 may correspond to transmitters of a Graphics Processing Unit (GPU), a switch (e.g., a high-speed network switch), a network adapter, a central processing unit (CPU), a data processing unit (DPU), etc.

Examples of the communication network 108 that may be used to connect the devices 110 and 112 include wires, conductive traces, bumps, terminals, optical fibers, or the like. In other embodiments, the communication network 108 can be a Peripheral Component Interconnect Express (PCIe) interconnect. PCIe is a high-speed interface standard used to connect various hardware components. It can be an interconnect for devices such as graphics cards (GPUs), solid-state drives (SSDs), network cards, and other peripherals. PCIe offers a scalable, high-speed, and point-to-point connection between devices, including CPUs, GPUs, memory, and the like. In other embodiments, the communication network 108 can be a high-speed interconnect, such as an interconnect that deploys the NVLink technology. The NVLink interconnect can be a GPU-GPU interconnect used between GPUs, a CPU-GPU interconnect between GPUs and CPUs, or an interconnect used between other devices. NVLink offers a higher bandwidth and lower latency than traditional PCIe connections, which are typically used in computing hardware. NVLink is especially useful in scenarios that require massive parallel processing, such as artificial intelligence (AI), machine learning, deep learning, high-performance computing (HPC), and data analytics. For example, in NVIDIA's DGX systems and high-end gaming or AI workstations, NVLink helps GPUs exchange data at speeds that are necessary for demanding tasks like real-time ray tracing or training neural networks. In one specific, but non-limiting example, the communication network 108 is a network that enables data transmission between the devices 110 and 112 using data signals (e.g., digital, optical, wireless signals), clock signals, or both. The embodiments described herein can be utilized in a system with a high-speed, scalable switch, such as a switch using the NVSwitch technology. NVSwitch is a high-speed, scalable switch developed by NVIDIA that facilitates data communication between multiple GPUs in a system, allowing them to work together more efficiently by providing high-bandwidth, low-latency interconnections. The NVSwitch serves as a central hub or high-bandwidth fabric that interconnects all the GPUs in a system, enabling each GPU to communicate with every other GPU quickly and efficiently. The NVSwitch can be coupled between other types of devices, such as CPUs, accelerators, memory, or the like. The NVSwitch can be used for tasks requiring intense computation and collaboration between multiple GPUs, such as AI model training, scientific simulations, and large-scale data processing. The embodiments described herein can be used in a high-performance computing system, such as a computing system modeled after NVIDIA's DGX systems, which are designed specifically for artificial intelligence (AI), deep learning, and high-performance computing (HPC) workloads. DGX systems are optimized for large-scale GPU computation and parallel processing, integrating multiple GPUs, high-bandwidth interconnects, and software frameworks tailored for AI and HPC tasks. In at least one embodiment, a system for high-speed network communication includes a processing unit, a network interface comprising a transmitter or transceiver with the duty-cycle correction circuit 142. In at least one embodiment, a system for high-speed network communication includes a processing unit, a network interface comprising a transmitter or transceiver with the duty-cycle correction circuit 142, as described herein. The processing unit can include a CPU, a GPU, a DPU, a network adapter, a network switch, an NVLink switch, or the like. 2436, as described herein.

Other examples for the communication network 108 can include other chip-to-chip or die-to-die interconnects, such as GRS, LPI (low power interface) or LLI (low latency interface).

The device 110 includes a transceiver 114 for sending and receiving signals, for example, data signals. The data signals may be digital or optical signals modulated with data or other suitable signals for carrying data.

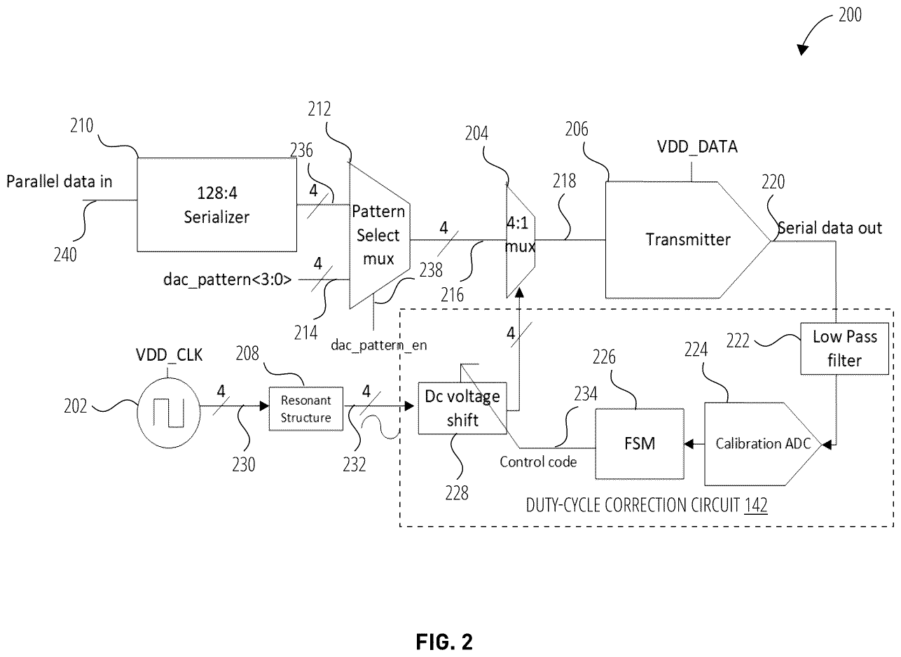

The transceiver 114 may include a digital data source 118, a transmitter 2402, a receiver 104, and processing circuitry 120 that controls the transceiver 114. The digital data source 118 may include suitable hardware and/or software for outputting data in a digital format (e.g., in binary code and/or thermometer code). The digital data output by the digital data source 118 may be retrieved from memory (not illustrated) or generated according to input (e.g., user input). The transceiver 114 can include the duty-cycle correction circuit 142 as described below with respect to FIG. 2 to FIG. 7

The transceiver 114 includes suitable software and/or hardware for receiving digital data from the digital data source 118 and outputting data signals according to the digital data for transmission over the communication network 108 to a transceiver 116 of device 112.

The receiver 104 of device 110 may include suitable hardware and/or software for receiving signals, for example, data signals from the communication network 108. For example, the receiver 104 may include components for receiving processing signals to extract the data for storing in a memory. In at least one embodiment, the transceiver 116 includes a transmitter 122 and receiver 140. The transceiver 116 receives an incoming signal and samples the incoming signal to generate samples, such as using an analog-to-digital converter (ADC). The ADC can be controlled by a clock-recovery circuit (or clock recovery block) in a closed-loop tracking scheme. The clock-recovery circuit can include a controlled oscillator, such as a voltage-controlled oscillator (VCO) or a digitally-controlled oscillator (DCO) that controls the sampling of the subsequent data by the ADC. The transceiver 116 can include the duty-cycle correction circuit 142 as described below with respect to FIG. 1A to FIG. 7.

The processing circuitry 120 may comprise software, hardware, or a combination thereof. For example, the processing circuitry 120 may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory). Additionally or alternatively, the processing circuitry 120 may comprise hardware, such as an Application-Specific Integrated circuit (ASIC). Other non-limiting examples of the processing circuitry 120 include an Integrated Circuit (IC) chip, a CPU, A GPU, a DPU, a microprocessor, a Field-Programmable Gate Array (FPGA), a collection of logic gates or transistors, resistors, capacitors, inductors, diodes, or the like. Some or all of the processing circuitry 120 may be provided on a Printed Circuit Board (PCB) or collection of PCBs. It should be appreciated that any appropriate type of electrical component or collection of electrical components may be suitable for inclusion in the processing circuitry 120. The processing circuitry 120 may send and/or receive signals to and/or from other elements of the transceiver 114 to control the overall operation of the transceiver 114.

The transceiver 114 or selected elements of the transceiver 114 may take the form of a pluggable card or controller for the device 110. For example, the transceiver 114 or selected elements of the transceiver 114 may be implemented on a network interface card (NIC).

The device 112 may include a transceiver 116 for sending and receiving signals, for example, data signals over a channel 106 of the communication network 108. The channel 2406 can be PCIe, NVLink, Ethernet, InfiniBand, Ground Reference Signal (GRS), Chip-to-Chip (C2C), Die-to-Die (D2D), or the like. The same or similar structure of the transceiver 114 may be applied to transceiver 116, and thus, the structure of transceiver 116 is not described separately.

Although not explicitly shown, it should be appreciated that devices 110 and 112 and the transceiver 114 and transceiver 116 may include other processing devices, storage devices, and/or communication interfaces generally associated with computing tasks, such as sending and receiving data.

FIG. 1B illustrates a block diagram of an example communication system 124 employing a transmitter 126 with a duty-cycle correction circuit 142 according to at least one embodiment. In the example shown in FIG. 1B, a Pulse Amplitude Modulation level-4 (PAM4) modulation scheme is employed with respect to the transmission of a signal (e.g., digitally encoded data) from a transmitter (TX) 126 to a receiver (RX) 130 via a communication channel 128 (e.g., a transmission medium). The communication channel 2406 can be PCIe, NVLink, Ethernet, InfiniBand, GRS, C2C, D2D, or the like. In this example, the transmitter 126 receives an input data 132 (i.e., the input data at time n is represented as “a(n)”), which is modulated in accordance with a modulation scheme (e.g., PAM4) and sends the signal 134 a(n) including a set of data symbols (e.g., symbols −3, −1, 1, 3, where the symbols represent coded binary data). It is noted that while the use of the PAM4 modulation scheme is described herein by way of example, other data modulation schemes can be used in accordance with embodiments of the present disclosure, including for example, a non-return-to-zero (NRZ) modulation scheme, PAM3, PAM7, PAM8, PAM16, etc. For example, for an NRZ-based system, the transmitted data symbols consist of symbols-1 and 1, with each symbol value representing a binary bit. This is also known as a PAM level-2 or PAM2 system as there are 2 unique values of transmitted symbols. Typically, a binary bit 0 is encoded as −1, and a bit 1 is encoded as 1 as the PAM2 values.

In the example shown, the PAM4 modulation scheme uses four (4) unique values of transmitted symbols to achieve higher efficiency and performance. The four levels are denoted by symbol values −3, −1, 1, 3, with each symbol representing a corresponding unique combination of binary bits (e.g., 00, 01, 10, 11).

The communication channel 128 is a destructive medium in that the channel acts as a low pass filter which attenuates higher frequencies more than it attenuates lower frequencies, introduces inter-symbol interference (ISI) and noise from cross talk, from power supplies, from Electromagnetic Interference (EMI), or from other sources. The communication channel 128 can be over serial links (e.g., a cable, PCB traces, copper cables, optical fibers, or the like), read channels for data storage (e.g., hard disk, flash solid-state drives (SSDs), high-speed serial links, deep space satellite communication channels, applications, or the like. The receiver (RX) 130 receives an incoming signal 136 over the communication channel 128. The receiver 130 can output a received signal 138, “v(n),” including the set of data symbols (e.g., symbols −3, −1, 1, 3, wherein the symbols represent coded binary data).

In at least one embodiment, the transmitter 126 can be part of a SerDes IC. The SerDes IC can be a transceiver that converts parallel data to serial data and vice versa. The SerDes IC can facilitate transmission between two devices over serial streams, reducing the number of data paths, wires/traces, terminals, etc. The receiver 130 can be part of a SerDes IC. The SerDes IC can include a clock-recovery circuit. The clock-recovery circuit can be coupled to an ADC and an equalization block. In another embodiment, the SerDes IC can include additional equalization block before a symbol detector.

FIG. 2 is a block diagram of a transmitter device 200 with a duty-cycle correction circuit according to at least one embodiment. The transmitter device 200 includes at least a clock source 202, a serializer 204, and a transmitter 206. The transmitter 206 can be considered an output driver of the serializer. It should be noted that although illustrated as a separate 4:1 multiplexer and transmitter, the serializer 204 can be represented as a single block with a 4:1 multiplexer and an output driver. For example, the transmitter device 200 can include a SerDes circuit that implements the 4:1 multiplexer and the transmitter 206 (i.e., output driver).

The serializers described herein can be used in high-speed data communication protocols, such as Ethernet (10G, 100G), PCIe, SATA, NVLink, and USB, as well as in wireless transmitters where they serialize data before modulating it onto an RF carrier. They are also essential in display interfaces like HDMI, DisplayPort, and LVDS, where they handle video and audio data transmission. The performance of a serializer depends on factors like the maximum achievable data rate, which is limited by the clock speed and circuit technology, as well as its ability to minimize jitter and noise for reliable data transmission. Encoding schemes used in serializers may introduce overhead, requiring a higher bit rate to transmit the same amount of data. In communication systems, a serializer is typically paired with a deserializer at the receiver device to reconstruct the original parallel data, forming a complete SERDES (serializer/deserializer) system. By efficiently converting parallel data to serial format, serializers enable high-speed, low-pin-count, and long-distance data transmission in modern digital systems.

It should be noted that to ensure signal integrity and facilitate synchronization at the receiver, many serializers include additional features like encoding schemes (e.g., 8b/10b encoding) to maintain DC balance and avoid baseline wander. That is the serializer 204 can include a data encoder for improved transmission characteristics. Some also incorporate pre-emphasis or equalization techniques to mitigate signal degradation over long transmission distances. The embodiments described herein can be used with these additional features.

As illustrated in FIG. 2, the clock source 202 can supply a plurality of phase signals 230. The transmitter device 200 can include a resonant structure 208 that receives the phase signals 230 and generates a plurality of sinusoidal phase signals 232. The sinusoidal phase signals 232 can be used by the serializer 204. The serializer 204 is illustrated as a 4:1 multiplexer. In other embodiments, the serializer 204 can be an 2^{N}:1 multiplexer, where N is a positive integer equal to or greater than 2 (i.e., N≥2). A serializer typically consists of a parallel-to-serial conversion logic, such as a shift register or multiplexer, that performs the bit-by-bit conversion. A serializer typically consists of a parallel-to-serial conversion logic, such as a shift register or multiplexer, that performs the bit-by-bit conversion. The clock source 202 and resonant structure 208 can be part of a clock unit that generates the high-speed clocks required for the serial output. The clock unit can use a phase-locked loop (PLL).

In the embodiment where the serializer 204 is a 4:1 multiplexer, the serializer 204 receives four clock signals, referred to herein as sinusoidal phase signals 232 since each phase signal is the same signal, separated by a specified degrees phase shift, such as a first phase signal having zero phase, a second phase signal having a 90-degrees phase shift from the first phase signal, a third phase signal having a 180-degrees phase shift from the first phase signal, and a fourth phase signal having a 270-degrees phase shift from the first phase signal. That is, each of the phase signals are shifted by a 90-degrees phase shift. In at least one embodiment, the sinusoidal phase signals 232 includes four phase clock outputs including a 0-phase clock (labeled clk0), a 90-degree phase clock (labeled clk90), a 180-degree phase clock (labeled clk 180), a 270-degree phase clock (labeled clk 270).

If the serializer 204 were a 2:1 multiplexer, then the serializer 204 would receive two phase signals, a first phase signal with zero degrees phase shift and a second phase signal with a 180-degrees phase shift from the first phase signal. Alternatively, any number of phase signals can be used by the serializer 204.

As described above, resonant structure 208 can receive rectangular-like clock signals from the clock source 202. For example, the clock source 202 can be a voltage clock source that generates a plurality of rectangular clock signals. The resonant structure 208 can cause these plurality of rectangular clock signals to become a plurality of sinusoidal clock signals, referred to herein as the plurality of sinusoidal phase signals 232.

The serializer 204 can receive parallel data 216 and convert the parallel data 216 to serial data using the plurality of sinusoidal phase signals 232. The transmitter 206 is coupled to an output of the serializer 204. The transmitter 206 can transmit the serial data 218 at an output node 220 of the transmitter device 200. The duty-cycle correction circuit 142 is coupled to the output node 220 of the transmitter 206. The duty-cycle correction circuit 142 can detect a common mode (CM) voltage deviation in the serial data 218, and correct the CM voltage deviation by applying a voltage offset to the plurality of sinusoidal phase signals 232. In at least one embodiment, the duty-cycle correction circuit 142 includes an LPF 222, a calibration ADC 224, FSM 226 (or other state machine logic), and a level shifter 228 (also referred to as an analog duty-cycle correction loop or voltage shifter). The LPF 222 can receive the serial data 218 and determine an average voltage of the serial data 218. The calibration ADC 224 can receive the average voltage from the LPF 222 and convert the average voltage to digital data. The FSM 226 can receive the digital data from the calibration ADC 224 and detect the CM voltage deviation using the digital data. The FSM 226 can determine a control code 234 corresponding to the voltage offset to be applied to the sinusoidal phase signals 232. In some cases, the FSM 226 can generate multiple codes, corresponding to different voltage offsets, for different combinations of the plurality of sinusoidal phase signals 232. The level shifter 228 can receive the control code 234 from the FSM 226 and adjust the plurality of sinusoidal phase signals according to the control code 234.

In at least one embodiment, as illustrated in FIG. 2, the clock source 202 generates four phase clock outputs, referred to as ck0, ck90, ck180, and ck270. The phase clock outputs become almost sinusoidal once passed through the resonant structure 208. The resonant structure 208 can be a resonant network of one or more elements. The serializer 204 can be a 4:1 multiplexer that uses the four phase clocks. The serializer 204 can have pulse generation using for clock signals and drive the serial data output. There can be non-ideal properties (also referred to as non-idealities) in select pulse generation and driving of the serial data by the serializer 204. The non-ideal properties can result in large TX common mode noise at the output node 220 when the clock signals'DC value is half the rail voltage (referred to as VDD_CLK) of the clock source 202 (i.e., 0.5*VDD_CLK). The clock signal's DC value is said to have balanced positive and negative excursions. The TX common mode voltage deviation from the DC value (i.e., average voltage) can be used to detect the non-ideal properties. By detecting the TX common mode voltage deviations, the non-ideal properties in the signal can be corrected by adjusting the DC voltage or average voltage using a voltage offset (also referred to as DC offset).

In order to isolate the non-idealities, the transmitter device 200 can use a balanced clock pattern (also referred to as DC balanced clock pattern) to detect the TX common mode voltage deviation. In at least one embodiment, the balanced clock pattern can be a 2T pattern or a 4T pattern. A 2T pattern is a periodic pattern that repeats every 2 time units (2T). Examples of the 2T pattern include “0101” or “1010.” A 4T pattern is a periodic pattern that repeats every 4 time units (4T). Examples of the 4T pattern include “0110”,” “1001,” “1100,” and “0011.” The 2T patterns of 0101 and 1010 have highest sensitivity but cannot be used to separate the first and third phase signals (i.e., clk0/clk180) from the second and fourth phase signals (i.e., clk 0/clk270). The 4T patterns of 0110 and 1001 can isolate the effect of first and third phase signals (i.e., clk0/clk180), whereas the 4T patterns of 1100 and 0011 can isolate the second and fourth phase signals (i.e., clk 90/clk270). In at least one embodiment, the 4T pattern (any of 0110/1001/1100/0011) can be used since it shows strongest correlation with pseudo-random binary sequence (PRBS) data in terms of an optimal DC voltage shift.

In at least one embodiment, the FSM 226 (or other state machine logic) can receive digital values representing the average voltage of the serial data 218. The FSM 226 can control a target voltage of the level shifter 228 (e.g., an analog duty-cycle correction loop) to correct the non-ideality in the serial data 218. The FSM 226 can implement an algorithm that detect the CM voltage deviation in the serial data 218 and apply a voltage offset to the level shifter 228 by determining a control code 234 corresponding to CM voltage deviation. The algorithm can be made insensitive to offset in the transmitter 206 by using complementary patterns and averaging calibrated codes, like in chopping operational amplifiers (op-amps). For example, averaging the patterns of 0101 and 1010 patterns can be used to determine a single control code 234 to adjust the DC voltage of the sinusoidal phase signals 232.

In at least one embodiment, the serializer 204 can receive parallel data 216 comprising a known data pattern. The serializer 204 can convert the known data pattern of the parallel data 216 into a balanced clock pattern in the serial data 218. For example, during a calibration mode, the serializer 204 can receive the parallel data 216 with the known data pattern from a storage location, from a controller, from one or more registers, etc. In another embodiment, the serializer 204 can selectively receive the parallel data 216 with the known data pattern using a pattern selection multiplexer 212. The pattern selection multiplexer 212 can receive both actual parallel data 236 from a data source and calibration parallel data 214 with the known data pattern (i.e., DC balanced clock pattern) for detecting and correcting for the TX common mode noise. The pattern selection multiplexer 212, in response to an enable signal 238, can select the calibration parallel data 214 instead of the actual parallel data 236, passing the calibration parallel data 214 as the parallel data 216 to the serializer 204. In at least one embodiment, the enable signal 238 can be sent by a controller, set in a register, or the like, in response to the transmitter device 200 being in a calibration mode. When the transmitter device 200 is not in the calibration mode, such as in a normal operating mode, the enable signal 238 can be disabled, resulting in the pattern selection multiplexer 212 passing the actual parallel data 236 as the parallel data 216 to the serializer 204.

In at least one embodiment, the actual parallel data 236 can be received from a serializer 210. The serializer 210 can be an 2^{N}:4 serializer, such as 8:4 serializer, 16:4 serializer, 32:4 serializer, 64:4 serializer, 128:4 serializer, etc. In this embodiment, the serializer 210 receives input parallel data 240 from a data source, such as a processing unit. The serializer 210 can convert the input parallel data 240 to the actual parallel data 236, such as during the normal operating mode. In at least one embodiment, the pattern selection multiplexer 212 can receive the actual parallel data 236 from the serializer 210 in a first mode and the calibration parallel data 214 in a second mode. In either the first mode or the second mode, the pattern selection multiplexer 212 can output the parallel data 216 to the serializer 204, which converts the parallel data 216 into the serial data 218. However, in the second mode, the serializer 204 can convert the known data pattern into the DC balanced clock pattern at the output node 220. The average voltage of the DC balanced clock pattern can be detected by the LPF 222 of the duty-cycle correction circuit 142. The calibration ADC 224 can digitize the average voltage for processing by the FSM 226. The FSM 226 can determine a control code 234 to adjust the DC voltage of the clocks. The level shifter 228 can use the control code 234 to adjust the DC voltage (average voltage) of the phase signals 230 being used by the serializer 204.

In at least one embodiment, the transmitter 206 can be a replica transmitter. The replica transmitter can be the same as an actual transmitter, but is not terminated so that the duty-cycle correction circuit 142 can avoid any dependency on the TX output termination states of a transmitter.

In at least one embodiment, the FSM 226 can determine a single control code 234 by averaging the CM voltage deviation for each of the 4T patterns. This allows a single control knob instead of separating controls for the in-phase and out-of-phase signals (i.e., iclk/qclk).

In at least one embodiment, the duty-cycle correction circuit 142 can include a duty-cycle voltage shifter. The duty-cycle correction circuit 142 can determine an amount of the CM voltage deviation for each one of two or more 4T patterns for the balanced clock pattern. For example, the CM voltage deviation can be determined for four 4T patterns. The duty-cycle correction circuit 142 can determine an average value for the amounts of the CM voltage deviation for the 4T patterns. The duty-cycle correction circuit 142 can determine, using the average value, a control code corresponding to the voltage offset. The duty-cycle correction circuit 142 can apply the control code to the duty-cycle voltage shifter to adjust the plurality of sinusoidal phase signals. In some embodiments, these operations can be performed by the FSM 226. In other embodiments, other digital logic or analog circuits can be used to perform these operations.

In at least one embodiment, the duty-cycle correction circuit 142 can determine, using the CM voltage deviation, a control code corresponding to the voltage offset, and apply the control code to the duty-cycle voltage shifter to adjust the plurality of sinusoidal phase signals.

In at least one embodiment, the duty-cycle correction circuit 142 can determine a first amount of the CM voltage deviation for a first 4T pattern for the balanced clock pattern. The duty-cycle correction circuit 142 can determine, using the first amount, a first control code corresponding to the voltage offset for the first phase signal and the third phase signal. The duty-cycle correction circuit 142 can determine a second amount of the CM voltage deviation for a second 4T pattern for the balanced clock pattern. The duty-cycle correction circuit 142 can determine, using the second amount, a second control code corresponding to the voltage offset for the second phase signal and the fourth phase signal. In this embodiment, the duty-cycle correction circuit 142 can apply the first control code to the duty-cycle voltage shifter to adjust the sinusoidal phase signals corresponding to the first phase signal and the third phase signal, and apply the second control code to the duty-cycle voltage shifter to adjust the sinusoidal phase signals corresponding to the second phase signal and the fourth phase signal.

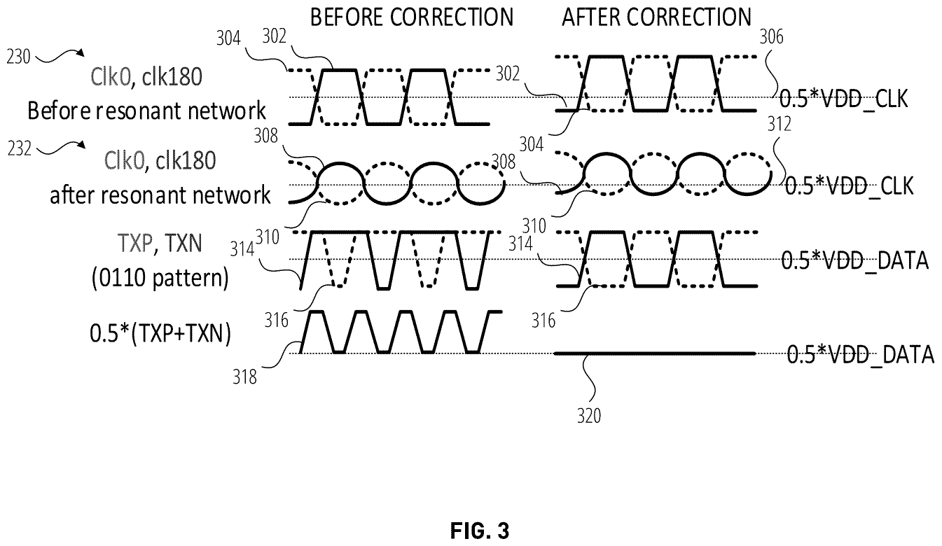

As described above, the duty-cycle correction circuit 142 can detect a CM voltage deviation in the serial data 218, and correct the CM voltage deviation by applying a voltage offset to the plurality of sinusoidal phase signals 232, such as illustrated in FIG. 3.

FIG. 3 illustrate timing diagrams of various signal waveforms before and after correction of the CM voltage deviation according to at least one embodiment. The signal waveforms include two of the phase signals 230, including a first phase signal 302 (clk0) and a third phase signal 304 (clk180) that is 180 degrees out of phase from the first phase signal 302. Before correction, an average voltage 306 (also referred to the “DC value”) of the first phase signal 302 and third phase signal 304 is roughly half the rail voltage of the clock source (i.e., 0.5*VDD_CLK). As described above, the first phase signal 302 and third phase signal 304 are passed through the resonant structure 208, which generates a first sinusoidal phase signal 308 and a third sinusoidal phase signal 310. Similarly, before correction, the average voltage 312 of the first sinusoidal phase signal 308 and third sinusoidal phase signal 310 is roughly half the rail voltage of the clock source (i.e., 0.5*VDD_CLK). A known data pattern of 0110 can be used to determine a CM voltage deviation 318 in the serial data. The transmitter can output a positive single-ended output 314 and a negative single-ended output 316, having an average voltage of half the rail voltage of the transmitter (i.e., 0.5*VDD_DATA). The positive single-ended output 314 (TXP) and the negative single-ended output 316 (TXN) make up a differential signal. Because of the CM noise in the serial data, the CM voltage deviation 318 is present in the serial data before correction. The CM voltage deviation 318 can be measured against a target.

After correction, the average voltage 306 is adjusted from being roughly half of the first phase signal 302 and third phase signal 304 and the average voltage 312 is adjusted such from being roughly half of the first sinusoidal phase signal 308 and third sinusoidal phase signal 310. In some cases, this calibration can be quite sensitive. Although FIG. 3 exaggerates the effect, even after calibration the averaged voltage of the clock signals will still be roughly around half of the VDD, but will be slightly shifted away from the original value (VDD/2) to minimize CM noise at TX output. After correction, as illustrated in FIG. 3, the CM noise can be removed from the serial data, resulting in no CM voltage deviation 320 (or reduced CM voltage deviation). The positive single-ended output 314 and negative single-ended output 316 are aligned to reduce the CM voltage deviation 318 to no CM voltage deviation 320 (or reduced CM voltage deviation). It should be noted that the CM noise reduction technique is designed for differential signaling systems, as it uses two differential signals (TXP/TXN) to extract the CM signal. The CM signal itself does not carry any information so the calibration minimizes the CM noise.

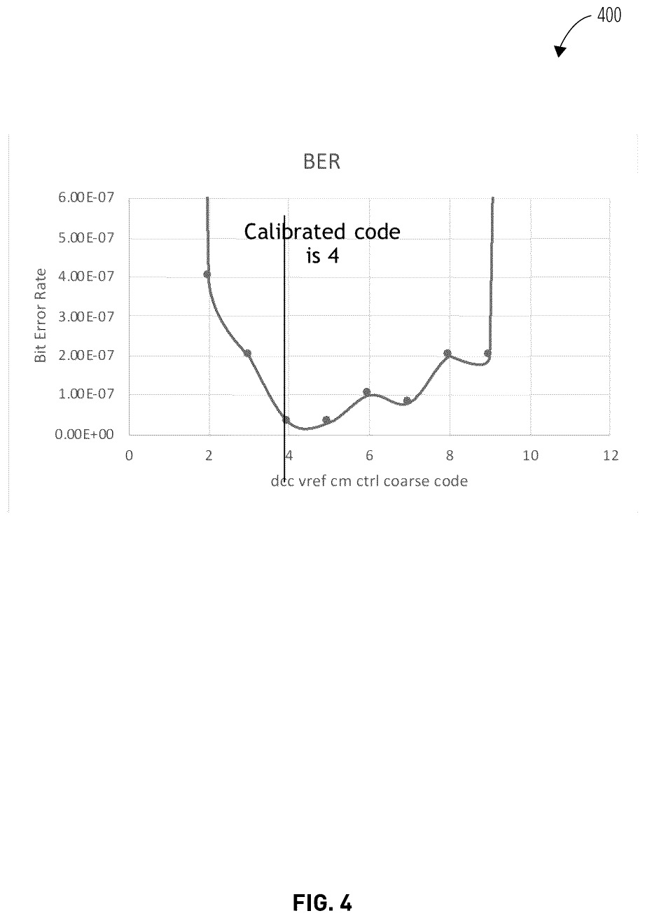

As described herein, the FSM 226 can determine a single control code 234 by averaging the CM voltage deviation from different patterns, such as illustrated and described below with respect to FIG. 4.

FIG. 4 is a graph 400 showing example BER for multiple calibration codes according to at least one embodiment. The graph 400 shows multiple data points representing the BER for a given control code. In this embodiment, the FSM can determine that the calibration code 4 should be used for the control code, as it results in the lowest BER. That is, the BER of the link is best for the calibrated code 4. The calibrated code 4 can be input as the voltage reference for the level shifter 228 (analog duty-cycle correction loop). This allows a single control knob instead of separating controls for the in-phase and out-of-phase signals (i.e., iclk/qclk). As described herein, the FSM can be made insensitive to offset in the transmitter 206 by using complementary patterns and averaging calibrated codes, like in chopping operational amplifiers (op-amps). For example, averaging the patterns of 0101 and 1010 patterns can be used to determine a single control code 234 to adjust the DC voltage of the sinusoidal phase signals 232.

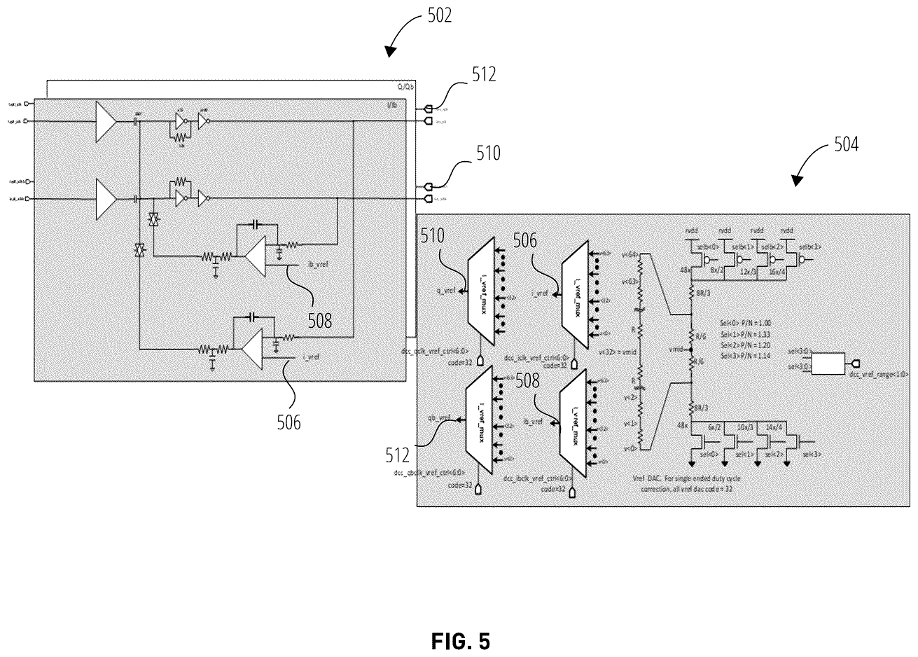

As described above, the level shifter 228 can receive a control code 234 from the FSM 226 to adjust a voltage offset. The level shifter 228 can include an analog duty-cycle correction loop and a Vref DAC, such as illustrated and described below with respect to FIG. 5.

FIG. 5 is a schematic diagram of an analog duty-cycle correction loop 502 and a Vref DAC 504 according to at least one embodiment. The Vref DAC 504 can receive the control code 234 to select one of multiple voltages generated by a resistor ladder network. The resistor ladder network can include a sequence of resistors coupled in series between a positive voltage potential and ground (or a negative voltage potential), where each node between the resistors can generate a specific voltage. Each of these nodes can be coupled as inputs to four multiplexers. The multiplexers can select one of the voltages based on the received code. The output of the four multiplexers are coupled as reference voltages in the analog duty-cycle correction loop 502. That is, the four multiplexers output a first voltage offset 506, a second voltage offset 508, a third voltage offset 510, and a fourth voltage offset 512, for each of the four clock paths. That is, each clock path includes a feedback path with an operational amplifier. The corresponding voltage offset can be added to the clock signals on the clock path to adjust the DC voltage of the clocks.

In at least one embodiment, the duty-cycle correction circuit includes a plurality of Vref DACs, each to receive the same control code corresponding to the voltage offset (or different control codes) and convert the control code into a voltage reference (Vref). A number of the plurality of Vref DACs can be equal to a number of the plurality of phase signals being used. The duty-cycle correction circuit can include a plurality of level shifters, each level shifter to receive one phase signal of the plurality of phase signals and the corresponding Vref from the plurality of Vref DACs and to increase or decrease a voltage amplitude of the one phase signal.

In other embodiments, the level shifter 228 can use other circuitry to adjust the DC voltage of the clock signals using the control code 234 as an input. For example, in some embodiments, instead of the FSM 226, a purely analog solution is possible to detect the CM voltage deviation and apply the appropriate voltage offsets to correct for the CM voltage deviation.

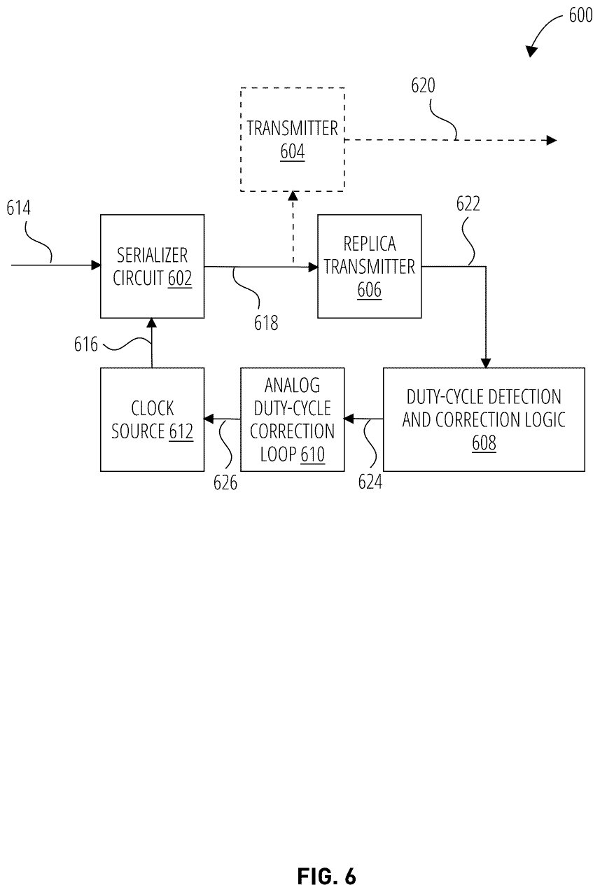

FIG. 6 is a block diagram of an interface circuit 600 with duty-cycle detection and correction logic 608 and an analog duty-cycle correction loop 610 according to at least one embodiment. The interface circuit 600 includes a serializer circuit 602, a transmitter 604, and a replica transmitter 606. The transmitter 604 can be terminated and the replica transmitter 606 can be used to remove any dependency on the terminated state of the interface circuit 600.

As illustrated in FIG. 6, the serializer circuit 602 receives calibration data 614 and clock signals 616 from a clock source 612. The clock source 612 can be a voltage clock source that generates a plurality of rectangular clock signals, and a resonant structure coupled to the voltage clock source. The resonant structure can receive the plurality of rectangular clock signals and generate a plurality of sinusoidal clock signals. The clock signals 616 can include the plurality of sinusoidal clock signals. The serializer circuit 602 converts the calibration data 614, using the clock signals 616, into serial data 618. The replica transmitter 606 is coupled to an output of the serializer circuit 602 and outputs an output signal 622 with the serial data. The duty-cycle detection and correction logic 608 can receive the output signal 622 (or a filtered version of the output signal). In at least one embodiment, the duty-cycle detection and correction logic 608 can include analog circuitry to measure an average voltage of the output signal 622. In another embodiment, the duty-cycle detection and correction logic 608 can include an ADC to obtain a digital value of the average voltage of the output signal 622. The duty-cycle detection and correction logic 608 can also include an LPF before the ADC to filter the output signal 622 before being input into the duty-cycle detection and correction logic 608. In other embodiments, there can be intervening circuitry between the replica transmitter 606 and the duty-cycle detection and correction logic 608. The duty-cycle detection and correction logic 608 can determine a CM voltage deviation in the serial data 618 using the average voltage. The duty-cycle detection and correction logic 608 can use the CM voltage deviation to control a target voltage 624 (i.e., a reference voltage) of the analog duty-cycle correction loop 610 to correct for the CM voltage deviation. The analog duty-cycle correction loop 610 can use the target voltage 624 to adjust a voltage offset in the clock signals 616 input into the serializer circuit 62.

In at least one embodiment, the interface circuit 600 may also include further includes a low-pass filter coupled to an output of the replica transmitter 606. The low-pass filter can filter the output signal to obtain a filtered signal. The interface circuit 600 can include an ADC coupled to the low-pass filter. The ADC can convert the filtered signal into digital data. The duty-cycle detection and correction logic 608 can include a FSM to determine the CM voltage deviation using the digital data and control the target voltage 624 of the analog duty-cycle correction loop 610.

In at least one embodiment, the interface circuit 600 may also include a second transmitter 604 coupled to an output node of the interface circuit 600. The replica transmitter 606 is a replica of the second transmitter 604. The replica transmitter 606 has no dependency on an output termination state of the output node of the interface circuit 600.

In at least one embodiment, the serializer circuit 602 includes a serializer, a pattern selection multiplexer, and a multiplexer, such as illustrated in FIG. 2. In some embodiments, the serializer circuit 602 can include a first serializer and a second serializer for the pattern selection multiplexer. The serializer of the serializer circuit 602 can receive input parallel data from a data source and output parallel data. The serializer can be a 2^{N}:4 serializer. The pattern selection multiplexer can receive the calibration data or the output parallel data from the serializer based on an enable signal. The pattern selection multiplexer can output data. The multiplexer can receive the output data from the pattern selection multiplexer and the clock signals from the clock source. The multiplexer is a 4:1 multiplexer. The multiplexer can receive four clock signals from the clock source. The multiplexer can output the serial data.

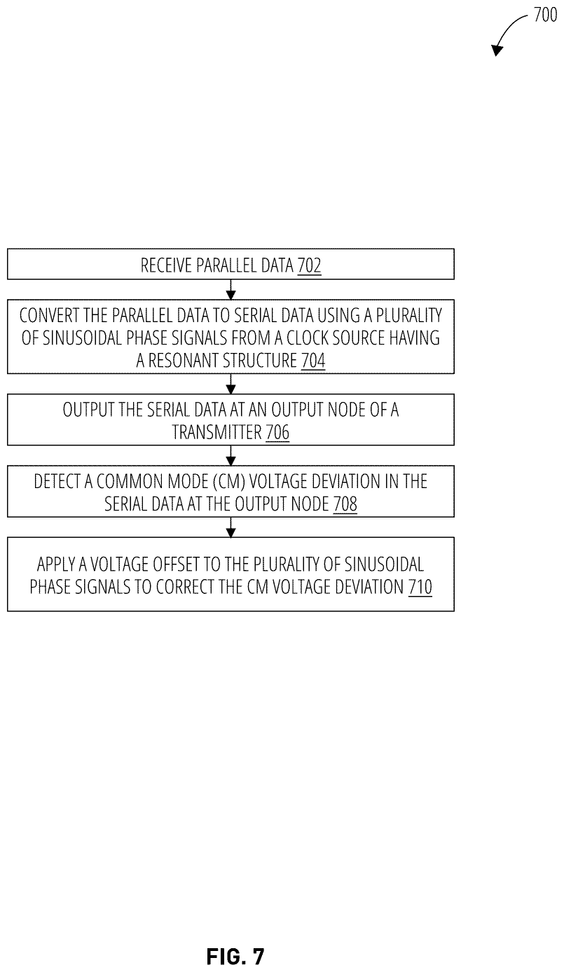

FIG. 7 is a flow diagram of an example method 700 for correcting a common mode voltage deviation according to at least one embodiment. Method 700 can be performed using one or more processing units (e.g., CPUs, GPUs, accelerators, physics processing units (PPUs), data processing units (DPUs), etc.), which may include (or communicate with) one or more memory devices. In at least one embodiment, method 700 can be performed using a processing device or processing devices. In at least one embodiment, method 700 can be performed using processing units of component of FIG. 1A and FIG. 1B (e.g., duty-cycle correction circuit 142). In at least one embodiment, method 700 can be performed by processing units of a component of FIG. 2 (e.g., duty-cycle correction circuit 142). In at least one embodiment, the method 700 can be performed by processing units of a component of FIG. 6 (e.g., interface circuit 600). In at least one embodiment, processing units performing the method 700 can be executing instructions stored on a non-transient computer readable storage media. In at least one embodiment, the method 700 can be performed using multiple processing threads (e.g., CPU threads and/or GPU threads), individual threads executing one or more individual functions, methods, subroutines, or operations of the method. In at least one embodiment, processing threads implementing any of method 700 can be synchronized (e.g., using semaphores, critical sections, and/or other thread synchronization mechanisms). Alternatively, processing threads implementing the method 700 can be executed asynchronously with respect to each other. Various operations of method 700 can be performed in a different order compared with the order shown in FIG. 7. Some operations of the method 700 can be performed concurrently with other operations. In at least one embodiment, one or more operations shown in FIG. 7 may not always be performed.

Referring to FIG. 7, the processing logic begins the method 700 by the processing logic receives parallel data (block 702). At block 704, the processing logic converts the parallel data to serial data using a plurality of sinusoidal phase signals from a clock source having a resonant structure. At block 706, the processing logic outputs the serial data at an output node of a transmitter. At block 708, the processing logic detects a common mode (CM) voltage deviation in the serial data at the output node. At block 710, the processing logic applies a voltage offset to the plurality of sinusoidal phase signals to correct the CM voltage deviation.

In at least one embodiment, the plurality of sinusoidal phase signals includes a first phase signal and a second phase signal, each separated by a 90-degrees phase shift. In at least one embodiment, the balanced clock pattern is a 2T pattern. In at least one embodiment, the plurality of sinusoidal phase signals includes a first phase signal, a second phase signal, a third phase signal, and a fourth phase signal, each separated by a 90-degrees phase shift. The balanced clock pattern is a 2T pattern or a 4T pattern. In a further embodiment, the processing logic determines an amount of the CM voltage deviation for each one of four 4T patterns for the balanced clock pattern. The processing logic determines an average value for the amounts of the CM voltage deviation for the four 4T patterns. The processing logic determines, using the average value, the voltage offset.

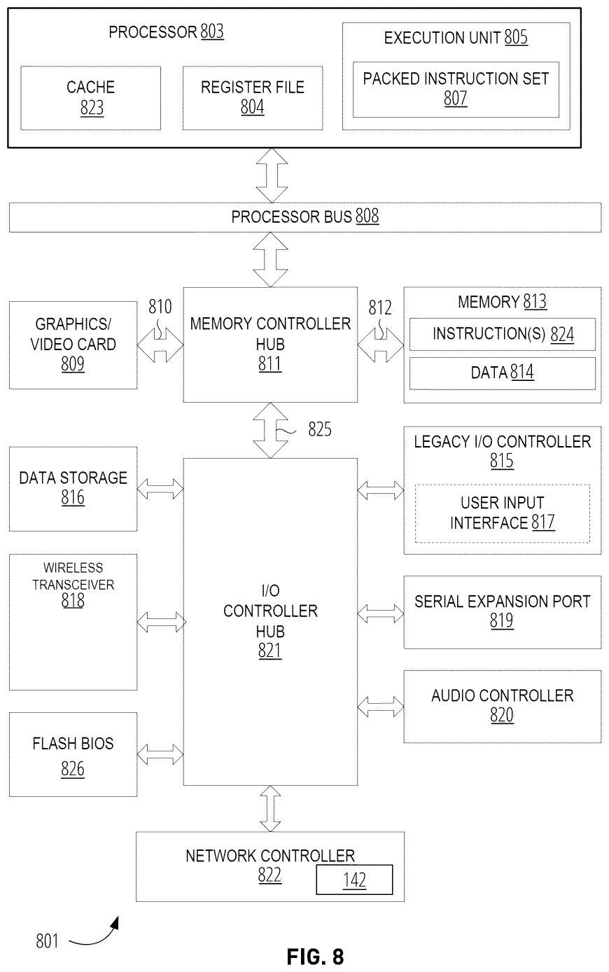

FIG. 8 illustrates an example computer system 801, including a duty-cycle correction circuit 142, in accordance with at least some embodiments. In at least one embodiment, computer system 801 may be a system with interconnected devices and components, an SOC, or some combination. In at least one embodiment, computer system 801 is formed with a processor 803 that may include execution units to execute an instruction. In at least one embodiment, computer system 801 may include, without limitation, a component, such as a processor 803, to employ execution units including logic to perform algorithms for processing data. In at least one embodiment, computer system 801 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 801 may execute a version of WINDOWS' operating system available from Microsoft Corporation of Redmond, Wash., although other operating systems (UNIX and Linux, for example), embedded software, and/or graphical user interfaces, may also be used.

In at least one embodiment, computer system 801 may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions. In an embodiment, computer system 801 may be used in devices such as graphics processing units (GPUs), network adapters, central processing units, and network devices such as switches (e.g., a high-speed direct GPU-to-GPU interconnect such as the NVIDIA GH100 NVLINK or the NVIDIA Quantum 2 64 Ports InfiniBand NDR Switch).

In at least one embodiment, computer system 801 may include, without limitation, processor 803 that may include, without limitation, one or more execution units 805 that may be configured to execute a Compute Unified Device Architecture (“CUDA”) (CUDA® is developed by NVIDIA Corporation of Santa Clara, CA) program. In at least one embodiment, a CUDA program is at least a portion of a software application written in a CUDA programming language. In at least one embodiment, computer system 801 is a single processor desktop or server system. In at least one embodiment, computer system 801 may be a multiprocessor system. In at least one embodiment, processor 803 may include, without limitation, a CISC microprocessor, a RISC microprocessor, a VLIW microprocessor, and a processor implementing a combination of instruction sets, or any other processor device, such as a digital signal processor, for example. In at least one embodiment, processor 803 may be coupled to a processor bus 808 that may transmit data signals between processor 803 and other components in computer system 801.

In at least one embodiment, processor 803 may include, without limitation, a Level 1 (“L1”) internal cache memory (“cache”) 823. In at least one embodiment, processor 803 may have a single internal cache or multiple levels of internal cache. In at least one embodiment, cache memory may reside external to processor 803. In at least one embodiment, processor 803 may also include a combination of both internal and external caches. In at least one embodiment, a register file 804 may store different types of data in various registers including, without limitation, integer registers, floating point registers, status registers, and instruction pointer register.

In at least one embodiment, execution unit 805, including, without limitation, logic to perform integer and floating point operations, also resides in processor 803. Processor 803 may also include a microcode (“ucode”) read only memory (“ROM”) that stores microcode for certain macro instructions. In at least one embodiment, execution unit 805 may include logic to handle a packed instruction set 807. In at least one embodiment, by including packed instruction set 807 in an instruction set of a general-purpose processor 803, along with associated circuitry to execute instructions, operations used by many multimedia applications may be performed using packed data in a general-purpose processor 803. In at least one embodiment, many multimedia applications may be accelerated and executed more efficiently by using full width of a processor's data bus for performing operations on packed data, which may eliminate a need to transfer smaller units of data across a processor's data bus to perform one or more operations one data element at a time.

In at least one embodiment, execution unit 806 may also be used in microcontrollers, embedded processors, graphics devices, DSPs, and other types of logic circuits. In at least one embodiment, computer system 801 may include, without limitation, a memory 813. In at least one embodiment, memory 813 may be implemented as a DRAM device, an SRAM device, flash memory device, or other memory devices. Memory 813 may store instruction(s) 824 and/or data 814 represented by data signals that may be executed by processor 803.

In at least one embodiment, a system logic chip may be coupled to a processor bus 808 and memory 813. In at least one embodiment, the system logic chip may include, without limitation, a memory controller hub (“MCH”) 811, and processor 803 may communicate with MCH 811 via processor bus 808. In at least one embodiment, MCH 811 may provide a high bandwidth memory path 812 to memory 813 for instruction and data storage and for storage of graphics commands, data, and textures. In at least one embodiment, MCH 811 may direct data signals between processor 803, memory 813, and other components in computer system 801 and may bridge data signals between processor bus 808, memory 813, and a system I/O 825. In at least one embodiment, a system logic chip may provide a graphics port for coupling to a graphics controller. In at least one embodiment, MCH 811 may be coupled to memory 813 through high bandwidth memory path 812, and graphics/video card 809 may be coupled to MCH 811 through an Accelerated Graphics Port (“AGP”) interconnect 810.

In at least one embodiment, computer system 801 may use system I/O 825 that is a proprietary hub interface bus to couple MCH 811 to I/O controller hub (“ICH”) 821. In at least one embodiment, ICH 821 may provide direct connections to some I/O devices via a local I/O bus. In at least one embodiment, a local I/O bus may include, without limitation, a high-speed I/O bus for connecting peripherals to memory 813, a chipset, and processor 803. Examples may include, without limitation, an audio controller 820, a firmware hub (“flash BIOS”) 726, a wireless transceiver 818, a data storage 816, a legacy I/O controller 815 containing a user input interface 817, a keyboard interface, a serial expansion port 819, such as a USB, and a network controller 822. In at least one embodiment, the network controller 822 includes the duty-cycle correction circuit 142 of FIG. 1A or FIG. 1B. The duty-cycle correction circuit 142 can be the duty-cycle correction circuit 142 of FIG. 2 or the duty-cycle detection and correction logic 608 of FIG. 6. Data storage 816 may comprise a hard disk drive, a floppy disk drive, a CD-ROM device, a flash memory device, or other mass storage device.

In at least one embodiment, FIG. 8 illustrates a system, which includes interconnected hardware devices or “chips.” In at least one embodiment, FIG. 8 may illustrate an example SoC. In at least one embodiment, devices illustrated in FIG. 8 may be interconnected with proprietary interconnects, standardized interconnects (e.g., PCIe), or some combination thereof. In at least one embodiment, one or more components of system 802 are interconnected using compute express link (“CXL”) interconnects.

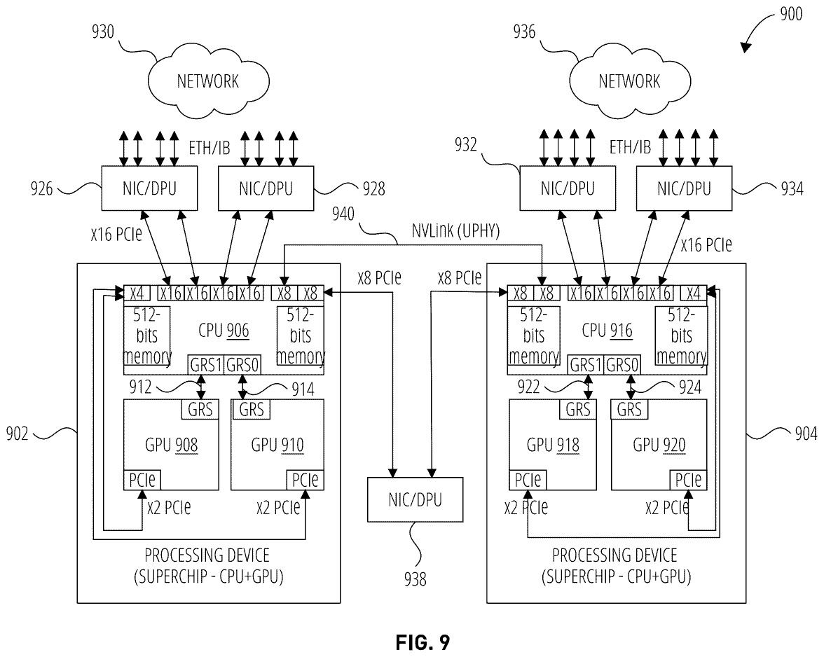

FIG. 9 is a block diagram of a computing system 900 having two processing devices coupled to each other and multiple networks according to at least one embodiment. The computing system 900 is designed with multiple integrated circuits (referred to as processing devices), where each integrated circuit includes a CPU and two GPUs, forming a powerful and flexible architecture. These processing devices are interconnected via an NVLink (or other high-speed interconnect), enabling high-speed communication between the processing devices, and are also connected through a Network Interface Card (NIC) or Data Processing Unit (DPU) to ensure efficient data transfer across the computing system 900. The coupling of processing devices through NVLink allows for seamless data exchange and parallel processing, enhancing overall computational performance. Additionally, these processing devices are connected to multiple networks through one or more network interface cards (NICs) or DPUs, enabling the system to handle complex, multi-network tasks with high bandwidth and low latency. This configuration makes the computing system 900 highly suitable for demanding applications that require significant processing power, such as artificial intelligence (AI), machine learning (ML), and data-intensive computing, while ensuring robust connectivity and scalability across various networked environments. The integrated circuits of the computing system 900 can include one or more CPUs and one or more GPUs. An example architecture of a multi-GPU architecture is illustrated in FIG. 9.

As illustrated in FIG. 9, the computing system 900 includes a processing device 902 with a multi-GPU architecture. In particular, the processing device 902 includes a CPU 906, a GPU 908, and a GPU 910. The CPU 906 can be coupled to the GPU 908 via an die-to-die (D2D) or chip-to-chip (C2C) interconnect 912, such as a Ground-Referenced Signaling interconnect (GRS interconnect). The CPU 906 can be coupled to the GPU 910 via a D2D or C2C interconnect 914. The CPU 906 can also couple to the GPU 908 and GPU 910 via PCIe interconnects. The CPU 906 can be coupled to one or more network interface cards (NICs) or data processing units (DPUs), which are coupled to one or more networks. For example, as illustrated in FIG. 9, the CPU 906 is coupled to a first NIC/DPU 926, which is coupled to a network 930. The CPU 906 is also coupled to a second NIC/DPU 928, which is coupled to the network 930. The NIC/DPU 926 and NIC/DPU 928 can be coupled to the network 930 over Ethernet (ETH) or InfiniBand (IB) connections.

The computing system 900 also includes a processing device 904 with a multi-GPU architecture. In particular, the processing device 904 includes a CPU 916, a GPU 918, and a GPU 920. The CPU 916 can be coupled to the GPU 918 via an D2D or C2C interconnect 922. The CPU 916 can be coupled to the GPU 920 via a D2D or C2C interconnect 924. The CPU 916 can also couple to the GPU 918 and GPU 920 via PCIe interconnects. The CPU 916 can be coupled to one or more NICs or DPUs, which are coupled to one or more networks. For example, as illustrated in FIG. 9, the CPU 916 is coupled to a first NIC/DPU 932, which is coupled to a network 936. The CPU 916 is also coupled to a second NIC/DPU 934, which is coupled to the network 936. The NIC/DPU 932 and NIC/DPU 934 can be coupled to the network 936 over Ethernet (ETH) or InfiniBand (IB) connections.

In at least one embodiment, the processing device 902 and the processing device 904 can communication with each other via a NIC/DPU 938, such as over PCIe interconnects. The processing device 902 and processing device 904 can also communicate with each other over a high-bandwidth communication interconnects 940, such as an NVLink interconnect or other high-speed interconnects. The NIC/DPUs of FIG. 9 can be the various embodiments of the DPUs described herein. The duty-cycle correction circuit 142 can be implemented in any receiver device of any of the devices described herein.

In at least one embodiment, the computing system 900 is used for high-speed network communication and includes a processing unit (e.g., CPU 906, GPU 908, GPU 910, CPU 916, GPU 918, GPU 920, NIC/DPU 926, NIC/DPU 928, NIC/DPU 932, NIC/DPU 934, or NIC/DPU 938), and a network interface coupled to the processing unit. The network interface can include the operations and functionality of the DPUs described herein.

In at least one embodiment, the computing system 900 includes a host device and an auxiliary device. The auxiliary device includes a device memory and a processor, communicably coupled to the device memory. The auxiliary device performs the operations described herein with respect to FIG. 2 to FIG. 7. The auxiliary device can include a GPU. The auxiliary device can include a DPU. The auxiliary device can include a DPU. The auxiliary device can include accelerator hardware.

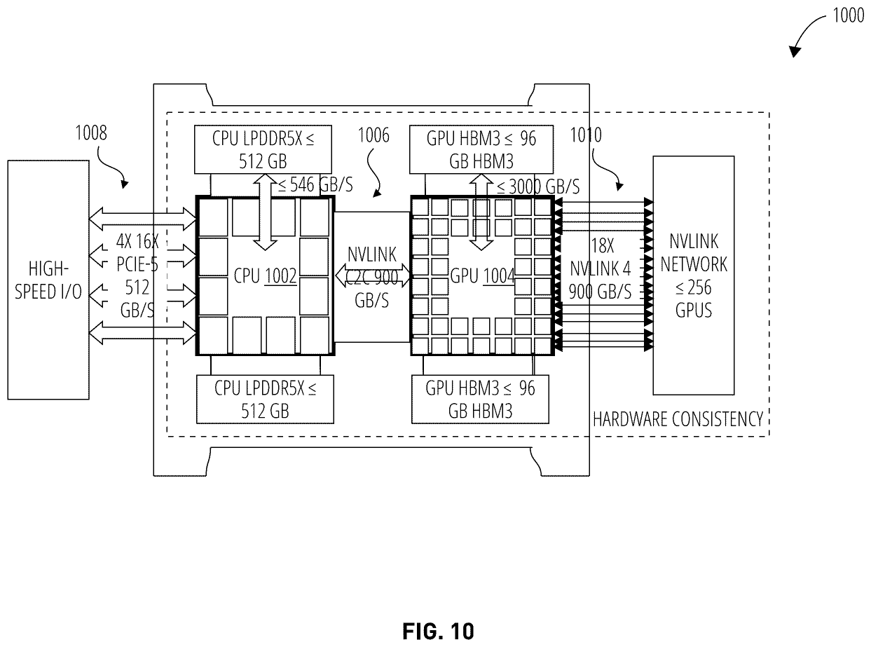

FIG. 10 is a block diagram of a computing system 1000 having a CPU 1002 and a GPU 1004 in a single integrated circuit according to at least one embodiment. The computing system 1000 can be a highly integrated design where a CPU 1002 and GPU 1004 are connected on a single integrated circuit, utilizing an NVLink C2C (Chip-to-Chip) interconnect 1006 to enable fast, low-latency communication between the two processing units. This close integration allows for efficient data transfer and parallel processing between the CPU 1002 and GPU 1004, optimizing performance for complex computational tasks. The GPU elements within the computing system 1000 can be interconnected using an NVLink network, allowing for scalability up to 256 GPU elements, creating a powerful, unified processing environment ideal for large-scale AI, ML, and high-performance computing applications. The NVLink network can be a GPU fabric of high-bandwidth communication interconnects 1010. Additionally, the computing system 1000 can be designed to interface with a high-speed I/O through PCIe interconnects 1008, ensuring rapid data transfer to and from external devices, further enhancing the system's capabilities in handling data-intensive tasks and providing robust connectivity to peripheral components. It should be noted that the C2C interconnects 1006 can be considered D2D interconnects since the CPU 1002 and the GPU 1004 are located on the same integrated circuit. The integrated circuit can include CPU memory (also referred to as main memory) and GPU memory, which are accessible by the CPU 1002 and the GPU 1004, respectively, over high-speed interconnects. The computing system 1000 can bring together performance of the GPU 1004 with the versatility of the CPU 1002. The CPU 1002 can be connected with a high-bandwidth and memory coherent C2C interconnects 1006 in a single integrated circuit. The computing system 1000 can support a link switch system.

The computing system 1000 can include the duty-cycle correction circuit 142 used for the various embodiments described herein with respect to FIG. 2 to FIG. 7. The duty-cycle correction circuit 142 can be implemented in any receiver device of any of the devices described herein.

In at least one embodiment, the computing system 1000 is used for high-speed network communication and includes a processing unit, and a network interface coupled to the processing unit. The network interface can include the operations and functionality of the DPUs described herein.

In at least one embodiment, the computing system 1000 includes a host device and an auxiliary device. The auxiliary device includes a device memory and a processor, communicably coupled to the device memory. The auxiliary device performs the operations described herein with respect to FIG. 2 to FIG. 7. The auxiliary device can include a GPU. The auxiliary device can include a DPU. The auxiliary device can include a DPU. The auxiliary device can include accelerator hardware.

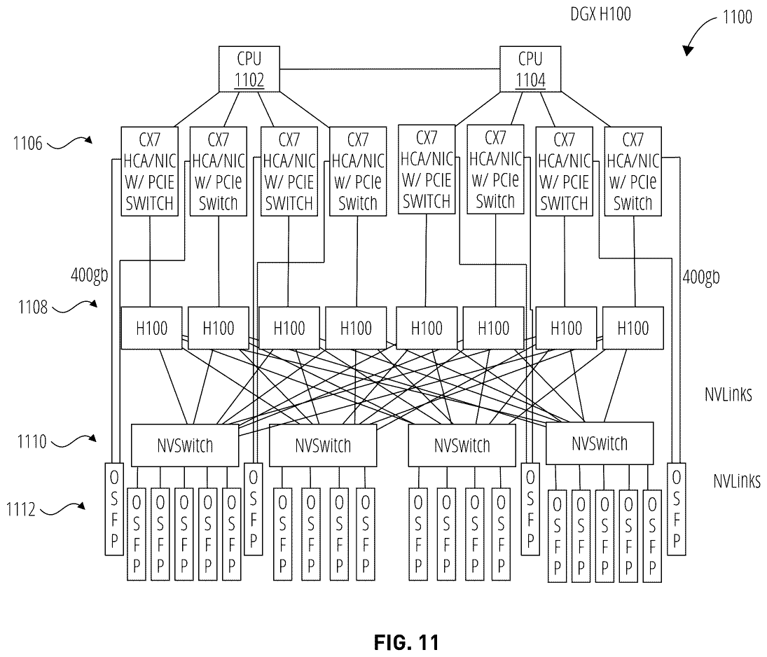

FIG. 11 is a block diagram of a computing system 1100 having tensor core GPUs 1108 according to at least one embodiment. The computing system 1100 can be a DGX H100 system, which is a high-performance computing platform designed to meet the demands of AI, ML, and deep learning (DL) workloads. The computing system 1100 can include multiple tensor core GPUs 1108 (e.g., NVIDIA H100 Tensor Core GPUs). The tensor core GPUs 1108 can each be one of the integrated circuits described above with respect to FIG. 10. The tensor core GPUs 1108 can be optimized for AI/ML/DL applications, offering exceptional performance for deep learning training, inference, and high-performance computing tasks. The tensor core GPUs 1108 within the computing system 1100 are interconnected using high-speed communication interfaces like NVLinks, enabling rapid data transfer between them, which is crucial for handling large-scale AI models and datasets with low latency. This computing system 1100 is designed for scalability, allowing for the integration of additional GPUs as required, making it versatile enough for research, development, and deployment in data centers for production AI workloads. Each GPU is equipped with Tensor Cores, specialized processing units that accelerate matrix operations, a fundamental component of AI and deep learning algorithms. These Tensor Cores enable the system to perform mixed-precision calculations efficiently, balancing speed and accuracy. Given the power consumption and heat generation of multiple tensor core GPUs 1108, the computing system 1100 can include advanced cooling solutions and power management features to ensure safe operation while maintaining peak performance. It is supported by a comprehensive software ecosystem, including NVIDIA's CUDA programming model, AI frameworks like TensorFlow and PyTorch, and other HPC and AI software tools, which enable developers and researchers to harness the full power of the tensor core GPUs 1108 for their specific applications. The computing system 1100 is ideally suited for large-scale AI model training, real-time inference, scientific simulations, data analytics, and other compute-intensive tasks that require massive parallel processing power.

The tensor core GPUs 1108 can be coupled to multiple CPUs, such as CPU 1102 and CPU 1104, using switches 1106 (e.g., CX7 HCA/NIC with PCIe switch). The tensor core GPUs 1108 can be coupled to each other via switches 1110 (e.g., NVSwitches). The switches 1106 and switches 1110 can be coupled to high-speed transceiver modules 1112. The high-speed transceiver modules 1112 can be Octal Small Form-factor Pluggable (OSFP) modules. OSFP modules refer to high-speed transceiver modules designed for rapid data communication, particularly in environments requiring significant bandwidth, such as data centers and high-performance computing systems. These modules support extremely high data rates, typically up to 400 Gbps per module, with future capabilities extending to 800 Gbps or more. OSFP modules interface with the system via the PCIe interface, enabling fast and efficient data transfer between the integrated CPU-GPU components and external networks or other connected systems. Their hot-pluggable nature allows for easy insertion or removal without the need to power down the system, offering flexibility and ease of maintenance, which is crucial in critical-uptime environments. Additionally, OSFP modules are designed for high density, maximizing the number of high-speed connections within limited space, such as in densely packed server racks. By adhering to the latest networking standards, OSFP modules ensure the computing system 1100 remains capable of meeting increasing data demands and can be upgraded to support future advancements in network speeds, thus contributing to the system's overall performance and scalability.

In at least one embodiment, the computing system 1100 can be considered a data-network configuration with full-bandwidth intra-server NVLinks. In this example, all eight tensor core GPUs 1108 can simultaneously saturate eighteen NVLinks to other GPUs within the server. The bandwidth is limited by over-subscription from multiple other GPUs. In another embodiments, data-network configuration can be a half-bandwidth intra-server NVLinks. In this example, all eight tensor core GPUs 1108 can half-subscribe eighteen NVLinks to GPUs in other servers. Four tensor core GPUs 1108 can saturate eighteen NVLinks to GPUs in other servers. This is equivalent of full-bandwidth on AllReduce with Scalable Hierarchical Aggregation and Reduction Protocol (SHARP). The reduction in all-2-all (All2All) bandwidth is a balance with server complexity and costs. In at least one embodiment, all eight tensor core GPUs 1108 can independently transfer data, using Remote Direct Memory Access (RDMA) protocol, over its own dedicated switch (e.g., 400 Gb/s HCA/NIC) in an multi-rail InfiniBand/Ethernet configuration. In this example, 800 GBps of aggregate full-duplex to non-NVLink network devices.

The NICs/switches of computing system 1100 can include the various embodiments described herein with respect to FIG. 2 to FIG. 7.

In at least one embodiment, the computing system 1100 is used for high-speed network communication and includes a processing unit (e.g., CPU 1102, CPU 1104, switches 1106, tensor core GPUs 1108, switches 1110, high-speed transceiver modules 1112), and a network interface coupled to the processing unit. The network interface can include a receiver or a transceiver and perform the corresponding operations and functionalities described herein. The processing unit can include a CPU, a GPU, a DPU, a network adapter, a network switch, an NVLink switch, or the like.

In at least one embodiment, the computing system 1100 includes a host device and an auxiliary device. The auxiliary device includes a device memory and a processor, communicably coupled to the device memory. The auxiliary device performs the operations described herein with respect to FIG. 2 to FIG. 7. The auxiliary device can include a GPU. The auxiliary device can include a DPU. The auxiliary device can include a DPU. The auxiliary device can include accelerator hardware.

Other variations are within the spirit of the present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, but on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. The term “connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within range unless otherwise indicated herein, and each separate value is incorporated into the specification as if it were individually recited herein. Use of the term “set” (e.g., “a set of items”) or “subset,” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but subset and corresponding set may be equal.

Conjunctive language, such as phrases of the form “at least one of A, B, and C,” or “at least one of A, B, and C,” unless specifically stated otherwise or otherwise clearly contradicted by context, is otherwise understood with the context as used in general to present that an item, term, etc., may be either A or B or C, or any nonempty subset of a set of A and B and C. For instance, in the illustrative example of a set having three members, conjunctive phrases “at least one of A, B, and C” and “at least one of A, B, and C” refers to any of the following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, the term “plurality” indicates a state of being plural (e.g., “a plurality of items” indicates multiple items). A plurality is at least two items but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. A set of non-transitory computer-readable storage media, in at least one embodiment, comprises multiple non-transitory computer-readable storage media, and one or more individual non-transitory storage media of multiple non-transitory computer-readable storage media lack all of the code while multiple non-transitory computer-readable storage media collectively store all of the code. In at least one embodiment, executable instructions are executed such that different instructions are executed by different processors-for example, a non-transitory computer-readable storage medium stores instructions, and a main CPU executes some of the instructions while a GPU executes other instructions. In at least one embodiment, different components of a computer system have separate processors, and different processors execute different subsets of instructions.

Accordingly, in at least one embodiment, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that the distributed computer system performs operations described herein and such that a single device does not perform all operations.

Use of any and all examples, or exemplary language (e.g., “such as”) provided herein, is intended merely to better illuminate embodiments of the disclosure, and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

The terms “coupled” and “connected,” along with their derivatives, may be used in the description and claims. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other but yet still CO-operate or interact with each other.

Unless specifically stated otherwise, it may be appreciated that throughout specification terms such as “processing,” “computing,” “calculating,” “determining,” or like, refer to action and/or processes of a computer or computing system or similar electronic computing devices, that manipulate and/or transform data represented as physical, such as electronic, quantities within computing system's registers and/or memories into other data similarly represented as physical quantities within computing system's memories, registers or other such information storage, transmission or display devices.

In a similar manner, the term “processor” may refer to any device or portion of a device that processes electronic data from registers and/or memory and transforms that electronic data into other electronic data that may be stored in registers and/or memory. As non-limiting examples, a “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes for carrying out instructions in sequence or parallel, continuously, or intermittently. The terms “system” and “method” are used herein interchangeably as far as a system may embody one or more methods, and methods may be considered a system.

In the present document, references may be made to obtaining, acquiring, receiving, or inputting analog or digital data into a subsystem, computer system, or computer-implemented machine. Obtaining, acquiring, receiving, or inputting analog and digital data can be accomplished in a variety of ways, such as by receiving data as a parameter of a function call or a call to an application programming interface. In some implementations, the process of obtaining, acquiring, receiving, or inputting analog or digital data can be accomplished by transferring data via a serial or parallel interface. In another implementation, the process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, the process of providing, outputting, transmitting, sending, or presenting analog or digital data can be accomplished by transferring data as an input or output parameter of a function call, a parameter of an application programming interface, or inter-process communication mechanism.

Although the discussion above sets forth example implementations of described techniques, other architectures may be used to implement the described functionality and are intended to be within the scope of this disclosure. Furthermore, although specific distributions of responsibilities are defined above for purposes of discussion, various functions and responsibilities might be distributed and divided in different ways, depending on circumstances.

Furthermore, although the subject matter has been described in language specific to structural features and/or methodological acts, it is to be understood that the subject matter claimed in appended claims is not necessarily limited to specific features or acts described. Rather, specific features and acts are disclosed as exemplary forms of implementing the claims.

What is claimed is:

1. A transmitter device comprising:
a clock source to supply a plurality of phase signals;
a resonant structure coupled to the clock source, the resonant structure to receive the plurality of phase signals and generate a plurality of sinusoidal phase signals;
a first serializer to receive parallel data and convert the parallel data to serial data using the plurality of sinusoidal phase signals;
a transmitter coupled to an output of the first serializer, the transmitter to transmit the serial data at an output node of the transmitter device; and
a duty-cycle correction circuit coupled to the output node, the duty-cycle correction circuit to detect a common mode (CM) voltage deviation in the serial data, and correct the CM voltage deviation by applying a voltage offset to the plurality of sinusoidal phase signals.

2. The transmitter device of claim 1, wherein the duty-cycle correction circuit comprises:
a low-pass filter (LPF) to receive the serial data and determine an average voltage of the serial data;
a calibration analog-to-digital converter (ADC) to receive the average voltage and convert the average voltage to digital data;
state machine logic to receive the digital data from the calibration ADC to detect the CM voltage deviation, and determine a control code corresponding to the voltage offset; and
an analog duty-cycle correction loop to receive the control code and adjust the plurality of sinusoidal phase signals according to the control code.

3. The transmitter device of claim 2, further comprising a low-pass filter (LPF) coupled between the output node and the calibration ADC.

4. The transmitter device of claim 1, further comprising:
a second serializer; and
a multiplexer coupled to the first serializer and the second serializer, the multiplexer to receive first parallel data from the second serializer in a first mode or second parallel data in a second mode, and output the parallel data, wherein the second parallel data comprising a known data pattern, wherein the first serializer, in the second mode, is to convert the known data pattern of the parallel data into a balanced clock pattern in the serial data.

5. The transmitter device of claim 4, wherein the plurality of phase signals comprises a first phase signal, a second phase signal, a third phase signal, and a fourth phase signal, each separated by a 90-degrees phase shift, and wherein the balanced clock pattern is a 2T pattern or a 4T pattern.

6. The transmitter device of claim 5, wherein the duty-cycle correction circuit comprises a duty-cycle voltage shifter, and wherein the duty-cycle correction circuit is to:
determine an amount of the CM voltage deviation for each one of four 4T patterns for the balanced clock pattern;
determine an average value for the amounts of the CM voltage deviation for the four 4T patterns;
determine, using the average value, a control code corresponding to the voltage offset; and
apply the control code to the duty-cycle voltage shifter to adjust the plurality of sinusoidal phase signals.

7. The transmitter device of claim 4, wherein the plurality of phase signals comprises a first phase signal and a second phase signal, each separated by a 90-degrees phase shift, and wherein the balanced clock pattern is a 2T pattern.

8. The transmitter device of claim 7, wherein the duty-cycle correction circuit comprises a duty-cycle voltage shifter, and wherein the duty-cycle correction circuit is to:
determine, using the CM voltage deviation, a control code corresponding to the voltage offset; and
apply the control code to the duty-cycle voltage shifter to adjust the plurality of sinusoidal phase signals.

9. The transmitter device of claim 4, wherein the plurality of phase signals comprises a first phase signal, a second phase signal, a third phase signal, and a fourth phase signal, each separated by a 90-degrees phase shift, and wherein the balanced clock pattern is a 4T pattern.

10. The transmitter device of claim 9, wherein the duty-cycle correction circuit comprises a duty-cycle voltage shifter, and wherein the duty-cycle correction circuit is to:
determine a first amount of the CM voltage deviation for a first 4T pattern for the balanced clock pattern;
determine, using the first amount, a first control code corresponding to the voltage offset for the first phase signal and the third phase signal;
determine a second amount of the CM voltage deviation for a second 4T pattern for the balanced clock pattern;
determine, using the second amount, a second control code corresponding to the voltage offset for the second phase signal and the fourth phase signal;
apply the first control code to the duty-cycle voltage shifter to adjust the sinusoidal phase signals corresponding to the first phase signal and the third phase signal; and
apply the second control code to the duty-cycle voltage shifter to adjust the sinusoidal phase signals corresponding to the second phase signal and the fourth phase signal.

11. The transmitter device of claim 1, wherein the duty-cycle correction circuit comprises:
a plurality of voltage reference digital-to-analog converters (Vref DACs), each to receive control code corresponding to the voltage offset and convert the control code into a voltage reference (Vref), wherein a number of the plurality of Vref DACs is equal to a number of the plurality of phase signals; and
a plurality of level shifters, each level shifter to receive one phase signal of the plurality of phase signals and the corresponding Vref from the plurality of Vref DACs and to increase or decrease a voltage amplitude of the one phase signal.

12. An interface circuit comprising:
a serializer circuit to receive calibration data and clock signals, and convert the calibration data, using the clock signals, into serial data having a known data pattern;
a transmitter coupled to the serializer circuit, the transmitter to receive the serial data and output an output signal with the serial data; and
duty-cycle detection and correction logic to determine a common mode (CM) voltage deviation in the serial data, and control a target voltage of an analog duty-cycle correction loop to correct for the CM voltage deviation; and
the analog duty-cycle correction loop to adjust a voltage offset in the clock signals input into the serializer circuit.

13. The interface circuit of claim 12, further comprising:
a low-pass filter coupled to an output of the transmitter, the low-pass filter to filter the output signal to obtain a filtered signal; and
an analog-to-digital converter (ADC) coupled to the low-pass filter, the ADC to convert the filtered signal into digital data, wherein the duty-cycle detection and correction logic comprises a finite state machine to determine the CM voltage deviation using the digital data and control the target voltage of the analog duty-cycle correction loop.

14. The interface circuit of claim 12, further comprising a second transmitter coupled to an output node, wherein the transmitter is a replica transmitter of the second transmitter, the replica transmitter having no dependency on an output termination state of the output node.

15. The interface circuit of claim 12, further comprising a clock source to generate the clock signals, wherein the serializer circuit comprises:
a serializer to receive input parallel data from a data source and output parallel data;
a pattern selection multiplexer coupled to the serializer, the pattern selection multiplexer to receive the calibration data or the output parallel data from the serializer based on an enable signal, and the pattern selection multiplexer to output data; and
a multiplexer to receive the output data from the pattern selection multiplexer and the clock signals from the clock source, the multiplexer to output the serial data.

16. The interface circuit of claim 15, wherein the serializer is a 2^{N}:4 serializer, wherein N is a positive integer equal to or greater than two, and wherein the multiplexer is a 4:1 multiplexer, and wherein the multiplexer is to receive four clock signals from the clock source.

17. The interface circuit of claim 15, wherein the clock source comprises:
a voltage clock source that generates a plurality of rectangular clock signals; and
a resonant structure coupled to the voltage clock source, the resonant structure to receive the plurality of rectangular clock signals and generate a plurality of sinusoidal clock signals, wherein the clock signals comprises the plurality of sinusoidal clock signals.

18. A method comprising:
receiving parallel data;
converting the parallel data to serial data using a plurality of sinusoidal phase signals from a clock source having a resonant structure;
outputting the serial data at an output node of a transmitter;
detecting a common mode (CM) voltage deviation in the serial data at the output node; and
applying a voltage offset to the plurality of sinusoidal phase signals to correct the CM voltage deviation.

19. The method of claim 18, wherein the plurality of sinusoidal phase signals comprises a first phase signal and a second phase signal, each separated by a 90-degrees phase shift, and wherein converting the parallel data to the serial data comprises converting a known data pattern of the parallel data into a balanced clock pattern in the serial data, wherein the balanced clock pattern is a 2T pattern.

20. The method of claim 18, wherein the plurality of sinusoidal phase signals comprises a first phase signal, a second phase signal, a third phase signal, and a fourth phase signal, each separated by a 90-degrees phase shift, and wherein converting the parallel data to the serial data comprises converting a known data pattern of the parallel data into a balanced clock pattern in the serial data, wherein the balanced clock pattern is a 2T pattern or a 4T pattern, wherein the method further comprises:
determining an amount of the CM voltage deviation for each one of four 4T patterns for the balanced clock pattern;
determining an average value for the amounts of the CM voltage deviation for the four 4T patterns; and
determining, using the average value, the voltage offset.

21. A system for high-speed network communication, the system comprising:
a processing unit; and
a network interface coupled to the processing unit, wherein the network interface comprises a transmitter device comprising:
a clock source to supply a plurality of phase signals;
a resonant structure coupled to the clock source, the resonant structure to receive the plurality of phase signals and generate a plurality of sinusoidal phase signals;
a first serializer to receive parallel data and convert the parallel data to serial data using the plurality of sinusoidal phase signals;
a transmitter coupled to an output of the first serializer, the transmitter to transmit the serial data at an output node of the transmitter device; and
a duty-cycle correction circuit coupled to the output node, the duty-cycle correction circuit to detect a common mode (CM) voltage deviation in the serial data, and correct the CM voltage deviation by applying a voltage offset to the plurality of sinusoidal phase signals.

22. The system of claim 21, wherein the processing unit comprises at least one of a central processing unit (CPU), a graphics processing unit (GPU), a data processing unit (DPU), a network adapter, a network switch, or an NVLink switch.
